(19) United States
(12) Patent Application Publication
(10) Pub. No.: US 2003/0209189 A1
(43) Pub. Date: Nov. 13, 2003

(54) Magnetic material and method for preparation thereof

(76) Inventor: Tetsuo Kado, Kure-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/431,365

(22) Filed: May 8, 2003

(30) Foreign Application Priority Data
May 13, 2002 (JP) 2002-137700

(51) Int. Cl. C30B 15/00; C30B 21/06; C30B 27/02; C30B 28/10; C30B 30/04

(52) U.S. Cl. 117/32

(57) ABSTRACT

The invention provides a novel magnetic material having an epitaxially grown single crystalline film of spinel ferrite such as hematite and magnetite as a magnetic layer formed on a substrate. In place of a single crystal substrate of, e.g., magnesium oxide, on which an epitaxial spinel ferrite film is directly grown, the spinel ferrite film in the inventive magnetic material is epitaxially grown on a mica plate as the substrate with intervention of a buffer layer which is a single crystalline thin film of magnesium oxide epitaxially grown on the substrate surface. The thus prepared magnetic material can be used in magnetic devices by virtue of the inexpensiveness and high magnetic properties.

### BACKGROUND OF THE INVENTION

The present invention relates to a novel magnetic material or, more particularly, to a magnetic material formed on a mica plate as a substrate in place of a synthetic single crystalline substrate which is considered indispensable when an epitaxially grown layer is to be formed on a substrate as well as to a method for the preparation of such a novel magnetic material.

It is heretofore usual that epitaxially grown films supported on a substrate in industrial applications are prepared by using a single crystal plate of, for example, silicon, gallium arsenide, magnesium oxide, sapphire or quartz as the substrate. These single crystalline substrate plates are unavoidably very expensive because the growing process of a single crystalline material must be conducted under utmost careful control by using an elaborately designed special apparatus consequently leading to unavoidable expensiveness of the electronic devices produced by using such a substrate.

In recent years, for example, single crystalline ferrite films are highlighted as a magnetic material used in filters, isolators, circulators and other devices in the microwave region in consideration of the outstandingly small loss by eddy currents. These single crystalline ferrite films heretofore, however, are very expensive since they are prepared by the epitaxial growth of a ferrite material on a single crystalline substrate of magnesium oxide, sapphire or others. This fact is the reason for the low prevalence of magnetic devices based on a single crystalline ferrite film notwithstanding the high magnetic performance of single crystalline ferrites per se. Accordingly, it is one of important problems in the field of ferrite-based magnetic materials to develop an inexpensive substrate material for epitaxial growth of single crystalline ferrites for magnetic devices.

### SUMMARY OF THE INVENTION

The present invention accordingly has an object, in view of the above-described problems in the magnetic materials, to provide a novel and inexpensive substrate material suitable for epitaxial growth of a single crystalline ferrite film thereon thereby to contribute to cost reduction of high-performance magnetic devices.

Thus, the magnetic material provided by the present invention is an integral layered body which comprises:

a plate of mica as a substrate;

a single crystalline layer of magnesium oxide formed on one surface of the substrate; and

a single crystalline film of a spinel ferrite formed on the layer of magnesium oxide.

The above-defined novel magnetic material of the invention can be prepared by a method which comprises the steps of:

forming a film of single-crystalline magnesium oxide having a thickness in the range from 5 nm to 20 nm by epitaxial growing on the surface of a mica plate as a substrate; and

forming a single-crystalline film of a spinel ferrite having a thickness in the range from 20 nm to 1000 nm by epitaxial growing of an iron oxide at a temperature in the range from 100° C. to 450° C. on the surface of the single-crystalline magnesium oxide film.

The iron oxide is preferably a composite metal oxide expressed by the formula M_{0.5}FeOₓ, in which M is a metallic element selected from the group consisting of Fe, Zn, Mn, Co, Ni, Cu, Mg and Li and the subscript x is a number in the range from 1.8 to 2.5. It is also preferable that the iron oxide is hematite or magnetite.

### BRIEF DESCRIPTION OF THE DRAWING

FIGS. 1A, 1B and 1C are RHEED pattern photographs of the mica substrate, buffer layer and single crystalline ferrite film, respectively, formed in the Example.

FIG. 2 is an X-ray diffractometric diagram of the magnetic material obtained in the Example.

FIG. 3 is a graph showing the B—H hysteresis curve of the magnetic material formed in the Example.

FIGS. 4A, 4B and 4C are RHEED pattern photographs of the mica substrate, buffer layer and single crystalline ferrite film, respectively, formed in the Comparative Example.

### DETAILED DESCRIPTION OF THE PREFERRED EMBODIMENTS

In the magnetic material of the present invention, the substrate for epitaxial film-forming thereon is a plate of mica which can be prepared by cutting a natural mica of about 1 mm thickness in the form of an about 20 mm by 20 mm square. Though not particularly limitative of the place of occurrence, magnetic materials of good quality can be prepared from natural mica plates occurring in the northern district of India. It is of course that artificial mica plates can be used for the purpose depending on the quality. The mineral type of the mica is not particularly limitative though with preference of muscovite mica and the like.

While a single crystalline film of spinel ferrite cannot be formed on a mica substrate directly by epitaxial growing, it is an unexpected discovery that an epitaxial single crystalline ferrite film can be readily formed on an epitaxially formed single crystalline layer of magnesium oxide formed on a mica substrate as an intermediate buffer layer.

In the preparation of the inventive magnetic material, accordingly, the first step of the preparation procedure is epitaxial growing of a single crystalline magnesium oxide buffer layer of 5 to 20 nm thickness on the mica substrate followed by second epitaxial growing of a single crystalline film of spinel ferrite having a desired thickness.

The mica plate used here as the substrate can be obtained by cleavage of a natural mica product without further treatment. It is preferable, however, that a mica plate obtained by cleavage is washed with a washing solvent such as acetone, ethyl alcohol, water and the like or, more preferably, washed with a phosphoric acid solution followed by rinse with water in order to remove impurities on the mica plate. This phosphoric acid treatment is performed by dipping the mica plate in an aqueous phosphoric acid solution of 5 to 20 mass % concentration at room temperature for 10 to 60 seconds.

The epitaxial growing of the single crystalline magnesium oxide layer on the mica substrate can be performed by a known method including vacuum vapor deposition, sputtering, chemical vapor deposition (CVD), ion plating and others. The vacuum vapor deposition method, which is a method in which metallic magnesium or magnesium oxide is heated and vaporized to cause deposition on the mica substrate in the presence of oxygen, is classified depending on the heating means of the vaporization source into the resistance-heating vapor deposition method, high-frequency heating vapor deposition method, electron-beam heating vapor deposition method and others, of which the electron-beam heating vapor deposition method is preferable because of the high purity of the epitaxial single crystalline film formed by deposition.

The chemical vapor deposition method is a method in which a magnesium halide is heated and vaporized and the vapor is reacted with an oxidizing agent such as oxygen, ozone and carbon monoxide in the vapor phase to cause deposition of magnesium oxide on the mica substrate as an epitaxially grown single crystalline film. In the sputtering method, metallic magnesium as a target is bombarded with accelerated ion beams to cause sputtering vaporization in an oxygen-containing atmosphere so that a single crystalline film of magnesium oxide is epitaxially grown on the mica substrate.

In the preparation of the inventive magnetic material, the quality of the magnesium oxide buffer layer is a very important factor having a great influence on the subsequent epitaxial growth of the single crystalline spinel ferrite film. When the magnesium oxide layer is formed by the electron-beam vapor deposition method, for example, the pressure of the vacuum atmosphere is kept preferably, in the range from 10⁻⁷ to 10⁻² Pa or, more preferably, at about 10⁻⁵ Pa. The rate of film forming should be as low as possible in order to obtain a single crystalline magnesium oxide film of high quality so that the film-forming rate at the initial stage is set preferably not to exceed 0.01 nm per second. Further, it is preferable that the temperature of the mica substrate during the magnesium oxide deposition is in the range from 0 to 700° C. or, more preferably, in the range from 350 to 450° C. The intermediate layer of magnesium oxide should have a thickness of at least 5 nm or, usually, a thickness in the range from 5 to 20 nm although higher crystallinity can be obtained by further increasing the thickness.

The next step is the epitaxial growing of a single crystalline film of spinel ferrite on the magnesium oxide buffer layer by using an iron oxide compound as the base material. The iron oxide base material is expressed by the general formula M_{0.5}FeOₓ, in which M is a metallic element selected from the group consisting of iron, zinc, manganese, cobalt, nickel, copper, magnesium and lithium and the subscript x is a number in the range from 1.8 to 2.5. When M is iron and x is 2 in the general formula, the iron oxide compound is magnetite Fe₃O₄ and, when M is iron and x is 9/4, the iron oxide compound is hematite Fe₂O₃. When M is not iron, a composite iron oxide resembling spinel ferrite is obtained. It is, however, practically a rather difficult matter that the atomic ratio of M:Fe in the ferrite material is exactly 0.5:1 allowing a small deviation so that the chemical composition of the ferrite material can be expressed by the formula M_{0.5+δ}Fe_{1-δ}Oₓ, in which δ is not smaller than −0.5 but smaller than 0.1.

The epitaxial growing method for the single crystalline spinel ferrite film can be the same as in the epitaxial growing of the magnesium oxide buffer layer on the mica substrate. For example, the electron-beam vapor deposition method is applicable here by using the above-described iron oxide compound as the target material and keeping the substrate at a temperature in the range from 100 to 450° C.

The vacuum pressure here is in the range from 10⁻⁵ to 10⁻² Pa or, preferably, at around 10⁻⁴ Pa because, when the pressure is too low, the ferrite film formed by vapor deposition suffers a large oxygen deficiency while, when the pressure is too high, the procedure of epitaxial growing is disturbed not to give a single crystalline film of good quality. The rate of film forming should be as low as possible. For example, the film forming rate in the initial stage is set at 0.01 nm per second and thereafter gradually increased to reach up to 0.1 nm per second.

By continuing the vapor deposition process in the above-described manner, an epitaxially grown single crystalline film of spinel ferrite is formed on the magnesium oxide layer in a thickness of 20 to 1000 nm or, preferably, 100 to 200 nm. A spinel ferrite film having a thickness smaller than 20 nm cannot be completely crystalline suffering insufficient ferrimagnetism as a magnetic material while, when the thickness is too large, an unduly long time is taken for film forming.

The thus formed single crystal of the spinel ferrite has a structure which can be identified by the observation of the RHEED (reflective high-energy electron beam diffraction) pattern in the course of film forming and X-ray diffraction pattern of the thin film.

The magnetic material of the present invention exhibits magnetic properties equivalent to or superior to the properties of conventional magnetic materials prepared by using a sapphire (00.1) substrate or a magnesium oxide (111) substrate.

In the following, the present invention is described in more detail by way of an Example which, however, never limits the scope of the invention in any way.

Apparatuses used in the following Example included a stainless steel-made vacuum chamber, an evacuation system consisting of a turbomolecular pump and a titanium getter pump, three electron-beam vapor deposition units, four film-thickness monitors of the quartz oscillator type and a molecular-beam epitaxy apparatus equipped with a RHEED unit capable of arriving at an ultimate vacuum of 1×10⁻⁸ Pa.

### EXAMPLE

A 20 mm by 20 mm square, 0.5 mm thick muscovite mica plate (001) for use as a vapor-deposition substrate was prepared by cleavage of a natural mica block and dipped for 30 seconds in a 10% by mass aqueous solution of phosphoric acid followed by ultrasonic washing in ultrapure water. The thus prepared mica plate was used as a substrate for epitaxial growth of a magnesium oxide buffer layer and a single crystalline thin film of ferrite by using a magnesium oxide pellet of 99.99% by mass purity and a disk-formed iron oxide Fe₂O₃ as the sources of electron beam vapor deposition.

Thus, the above-described mica plate was set in the vacuum chamber of a molecular-beam epitaxial apparatus and a buffer layer of a single crystalline magnesium oxide film having a thickness of 15 nm was epitaxially grown on the mica plate at a temperature of 400° C. Thereafter, a single crystalline film of iron oxide Fe₂O₃ having a thickness as a magnetic layer of 170 nm was epitaxially grown on the buffer layer also at 400° C. to prepare a magnetic material. The pressure of the vacuum chamber was kept at 4×10⁻⁴ Pa during the above procedure. The growth rates of the epitaxial films were in the range from 0.004 to 0.015 nm/second.

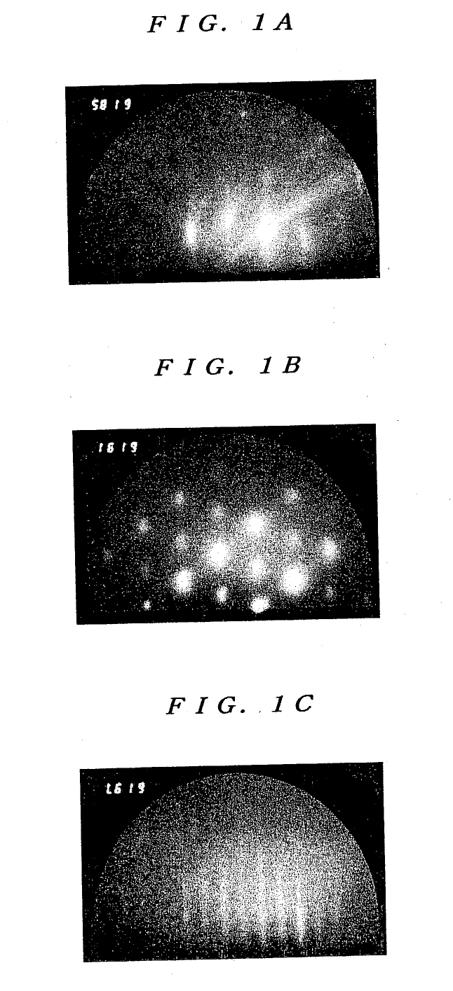

The epitaxial growing condition of the vapor-deposited films was examined by the RHEED observation at an electron beam acceleration voltage of 20 kV. The results are shown by the RHEED patterns given as FIGS. 1A, 1B and 1C for the mica substrate, magnesium oxide buffer layer and iron oxide magnetic layer, respectively.

The RHEED pattern of the mica substrate before vapor deposition shown in FIG. 1A, in which a Kikuchi line is found as a bright line running aslant from upper right to lower left, indicates a good satisfactory surface condition of the mica substrate.

FIG. 1B shows a RHEED pattern after formation of the buffer layer, in which the bright spot-wise pattern indicates the epitaxial growth of the magnesium oxide film in the direction of [111].

FIG. 1C shows a RHEED pattern after formation of a single crystalline film of iron oxide by the vapor deposition of hematite on the magnesium oxide buffer layer indicating epitaxial growth of a thin film of spinel ferrite in the [111] direction. Appearance of sharp streaks in the photograph is suggestive of the high crystallinity of the iron oxide layer.

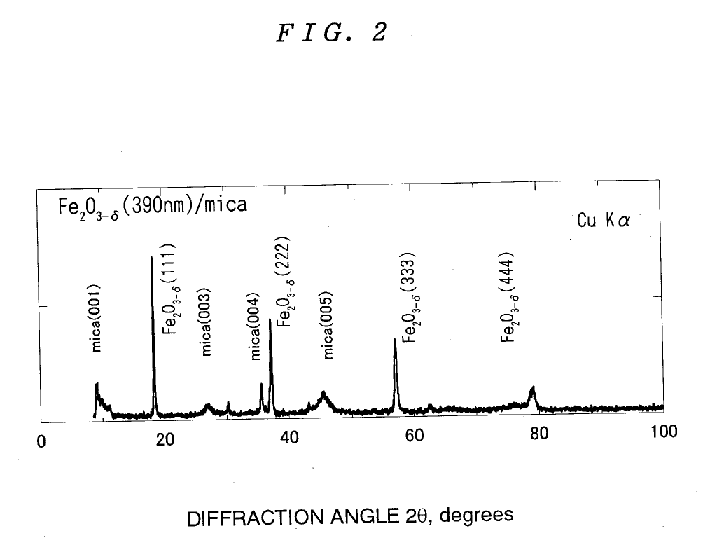

FIG. 2 is an X-ray diffraction pattern of the magnetic material prepared as described above, in which 4 (hhh) diffraction lines of the ferrite are clearly found along with the (00h) diffraction lines of mica indicating epitaxial growth of the spinel ferrite film on the mica substrate with intervention of a buffer layer of magnesium oxide.

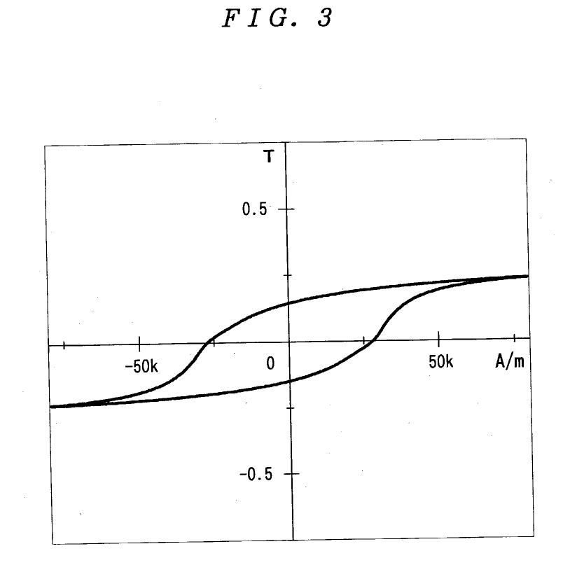

FIG. 3 shows a B—H hysteresis curve of the magnetic material obtained by using a vibration-sample magnetometer, which clearly indicates the phenomenon of magnetic hysteresis in the saturation magnetic flux density. The values of saturation magnetic flux density Bs and coercive force Hc were 0.23 T and 27 kA/m, respectively. These magnetic properties support a conclusion that the above-prepared magnetic material having a magnetic layer of spinel ferrite epitaxially grown in the [111] direction on a mica substrate is satisfactory as a magnetically soft material, in particular, in respect of the small coercive force Hc as compared with a similar magnetic material prepared by epitaxial growth of a spinel ferrite single crystalline film in the [111] direction on a sapphire substrate at the same temperature which has a saturation magnetic flux density Bs of 0.55T and coercive force of 31 kA/m.

### COMPARATIVE EXAMPLE

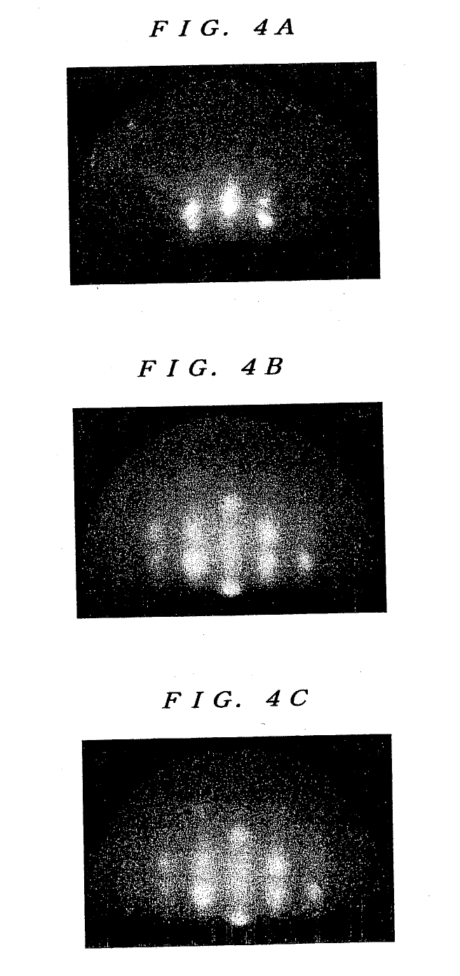

The mica substrate used here was a muscovite mica plate obtained by cleavage and successively ultrasonic-washed in acetone, ethyl alcohol and pure water followed by a heat treatment in a vacuum chamber at 600° C. for 5 minutes. A magnetic material was prepared by using this mica plate as the substrate in the same manner as in Example excepting for the use of, as the electron beam vapor-deposition sources, a disk of iron oxide Fe₃O₄ having a purity of 99% by mass and a pellet of magnesium oxide having a purity of 99.99% by mass to effect epitaxial growing of a 16 nm thick single crystalline film of magnetite with intervention of a 15 nm thick buffer layer of a single crystalline magnesium oxide film. FIGS. 4A, 4B and 4C show the RHEED patterns of this magnetic material, of which FIG. 4A is the pattern of the mica substrate as prepared. FIG. 4B is the pattern after film-formation of the 15 nm thick magnesium oxide buffer layer at 150° C. Though streaky, the broadness of the pattern is suggestive that the crystallinity of the buffer layer is low even by the epitaxial growing of the magnesium oxide film.

FIG. 4C is the RHEED pattern after formation of a 16 nm thick magnetite film. This pattern supports the epitaxial growth of the magnetite film even if it should be admitted that the crystallinity of the epitaxial film is not quite high. Due to the low crystallinity and small thickness of the ferrite film, no diffraction lines could be detected in the X-ray diffractometry. No ferrimagnetism could be detected in the magnetic material by the measurement of the B—H magnetic hysteresis curve conducted in the same manner as in Example.

What is claimed is:

1. A magnetic material which is an integral layered body comprising:
a plate of mica as a substrate;
a single crystalline film of magnesium oxide having a thickness of at least 5 nm epitaxially grown, as an intermediate layer, on one surface of the substrate; and
a single crystalline film of spinel ferrite having a thickness in the range from 20 to 1000 nm epitaxially grown, as a magnetic layer, on the intermediate layer.

2. A method for the preparation of the magnetic material defined in claim 1 which comprises the steps of:
epitaxially growing a single crystalline film of magnesium oxide as an intermediate layer on one surface of a mica substrate; and
epitaxially growing a single crystalline film of spinel ferrite at a temperature in the range from 100 to 450° C. on the intermediate layer by a method of vapor deposition using an iron oxide compound as a vaporization source.

3. The method according to claim 2 in which the iron oxide compound has a chemical composition expressed by the formula M_{0.5}FeOₓ, in which the subscript x is a number in the range from 1.8 to 2.5 and M is a metallic element selected from the group consisting of iron, zinc, manganese, cobalt, nickel, copper, magnesium and lithium.

4. The method according to claim 2 in which the iron oxide compound is hematite or magnetite.
